(19) United States
(12) Patent Application Publication
(10) Pub. No.: US 2008/0105409 A1
(43) Pub. Date: May 8, 2008

(54) HEAT DISSIPATION DEVICE WITH HEAT PIPES

(75) Inventors: WEN-LI LUO, Shenzhen (CN); SHI-WEN ZHOU, Shenzhen (CN); CHUN-CHI CHEN, Taipei Hsien (TW)

Correspondence Address: PCE INDUSTRY, INC.;ATT. CHENG-JU CHIANG, 458 E. LAMBERT ROAD, FULLERTON, CA, 92835, US

(73) Assignee: Foxconn Technology Co., Ltd., Taipei Hsien (TW)

(21) Appl. No.: 11/556,556

(22) Filed: Nov. 3, 2006

(51) Int. Cl. H05K 7/20

(52) U.S. Cl. 165/104.33; 165/80.3; 361/700

(57) ABSTRACT

A heat dissipation device includes a base for absorbing heat from a heat generating device and a first fin set disposed on the base. Two second fin sets are located on two sides of the first fin set and extend beyond the base. At least a heat pipe includes a first section thermally sandwiched between the base and the first fin set and extending totally within and thermally contacting with the two second fin sets, and a second section extending away from the base and thermally contacting the first fin set and the second fin set.

### BACKGROUND OF THE INVENTION

1. Field of the Invention

The present invention relates to heat dissipation devices for use in removing heat from electronic devices, and more particularly to a heat dissipation device incorporating heat pipes for improving heat dissipation efficiency of the heat dissipation device.

2. Description of Related Art

During operation of an electronic device such as a computer central processing unit (CPU), a large amount of heat is often produced. The heat must be quickly removed from the CPU to prevent it from becoming unstable or being damaged. Typically, a heat dissipation device is attached to an outer surface of the CPU to absorb heat from the CPU. The heat absorbed by the heat dissipation device is then dissipated to ambient air.

Conventionally, a heat dissipation device comprises a solid metal base attached to the CPU, and a plurality of fins arranged on the base. The base is intimately attached to the CPU thereby allowing it to absorb the heat generated by the CPU. Most of the heat accumulated at the base is transferred firstly to the fins and then dissipates away from the fins. However, as electronics technology continues to advance, increasing amounts of heat are being generated by powerful state-of-the-art CPUs. As a result, many conventional heat dissipation devices are no longer able to efficiently remove heat from these CPUs.

In order to overcome the above problems, one type of heat dissipation device used with the electronic devices includes a heat pipe for transferring heat from one part to another part of the heat dissipation device. A heat pipe is a vacuum-sealed pipe that is filled with a phase changeable fluid, usually being a liquid such as water, alcohol, acetone or the like, and has an inner wall thereof covered with a capillary system. As the electronic device heats up, a hot section (usually called an evaporating section) of the heat pipe which is located close to the electronic device also heats up. The liquid in the evaporating section of the heat pipe evaporates and the resultant vapor reaches a cool section (usually called a condensing section) of the heat pipe and condenses therein. The condensed liquid then flows to the evaporating section along the capillary system of the heat pipe. This evaporating/condensing cycle repeats and since the heat pipe transfers heat so efficiently, the evaporating section is kept at or near the same temperature as the condensing section of the heat pipe. As a result, heat-transfer capability of the heat dissipation device including such a heat pipe is greatly improved.

Typically, a heat dissipation device comprises a base, a plurality of fins located on the base and a heat pipe thermally connecting the base and the fins for transferring heat from the base to the fins. The heat pipe is U-shaped and comprises an evaporating section contacting the base, a condensing section parallel to the evaporating section and extending away from the base, and a connecting section connecting the evaporating section and the condensing section. The fins define a through channel receiving the condensing section therein. In use, the base absorbs heat generated by the electronic device. The evaporating section of the heat pipe is heated up and transfers the heat to the condensing section. Finally, via the condensing section of the heat pipe, the heat reaches the fins to be dissipated to ambient air. However, in this heat dissipation device, the great heat transfer capacity of the heat pipe cannot be fully utilized.

What is needed, therefore, is a heat dissipation device which can achieve a greater heat dissipation capability.

### SUMMARY OF THE INVENTION

A heat dissipation device in accordance with a preferred embodiment of the present invention comprises a base for absorbing heat from a heat generating device and a first fin set disposed on the base. Two second fin sets are located at two sides of the first fin set and extend beyond the base. At least a heat pipe comprises a first section thermally sandwiched between the base and the first fin set and extending through and totally within the two second fin sets, and a second section extending away from the base and thermally contacting the first fin set and the second fin set.

Other advantages and novel features of the present invention will become more apparent from the following detailed description when taken in conjunction with the accompanying drawings, in which:

### BRIEF DESCRIPTION OF THE DRAWINGS

Many aspects of the present apparatus can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is an exploded, isometric view of a heat dissipation device in accordance with a preferred embodiment of the present invention;

FIG. 2 is an assembled view of the heat dissipation device of FIG. 1;

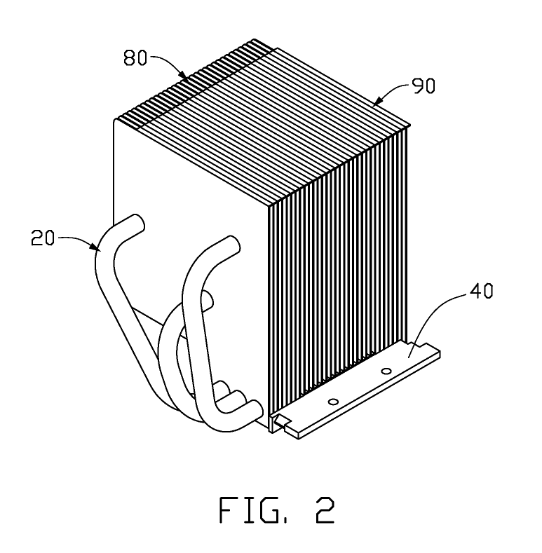

FIG. 3 is an assembled view of the heat dissipation device of FIG. 1 viewed from a bottom aspect; and

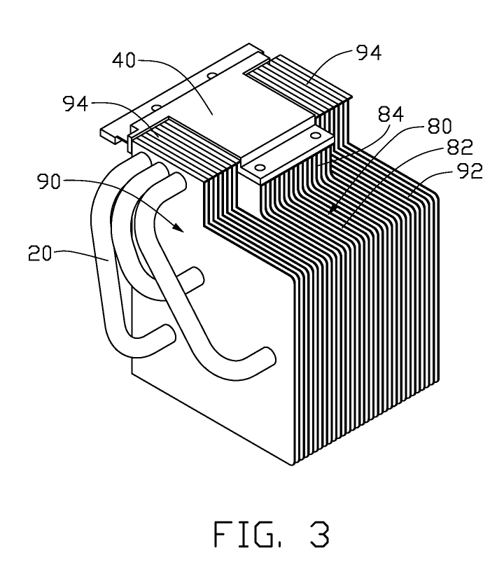

FIG. 4 is an assembled view of the heat dissipation device of FIG. 1, wherein a base of the heat dissipation device is removed.

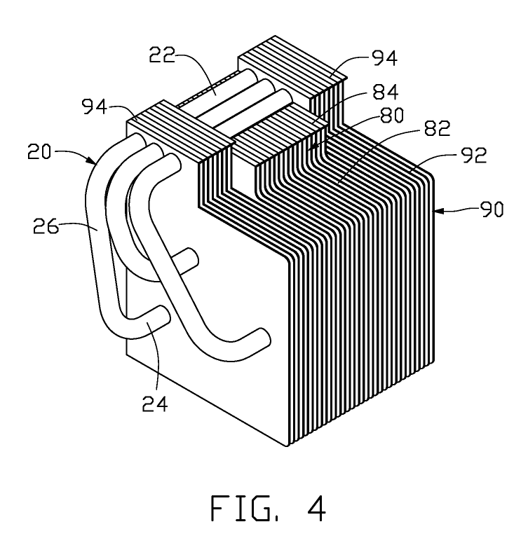

### DETAILED DESCRIPTION OF THE INVENTION

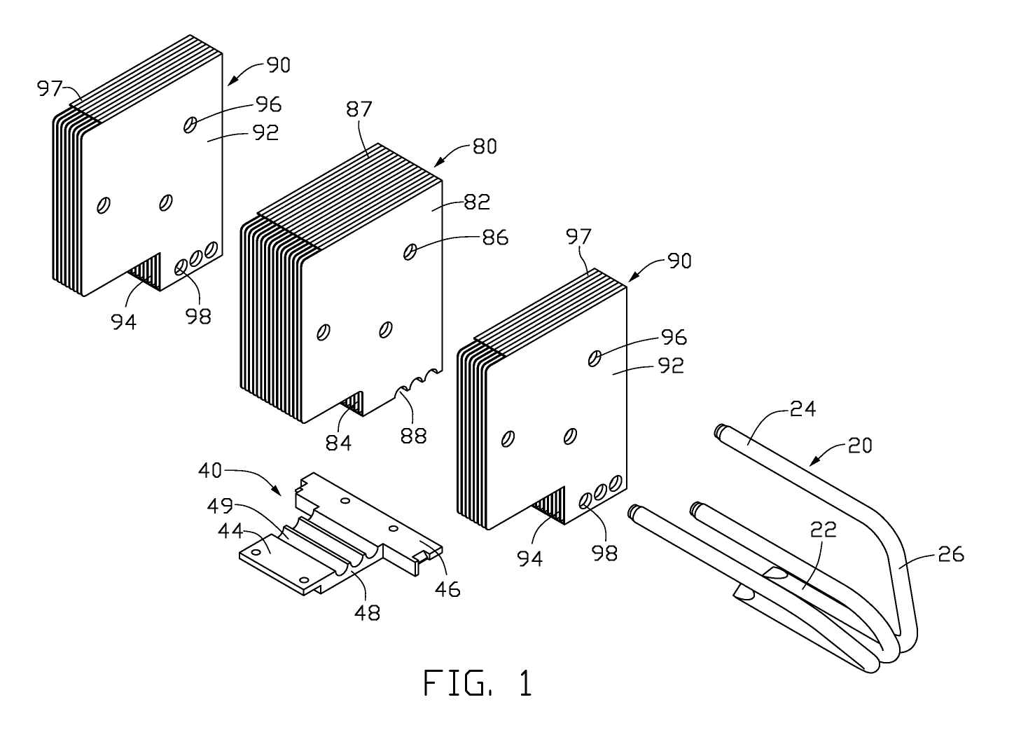

Referring to FIG. 1, a heat dissipation device in accordance with a preferred embodiment of the invention comprises a base 40, a first fin set 80 located on the base 40, two second fin sets 90 located at two sides of the first fin set 80, and a plurality of heat pipes 20 thermally connecting the first, second fin sets 80, 90 and the base 40.

The base 40 is made of metal having excellent heat conduction properties, such as copper, aluminum and the like. The base 40 is substantially T-shaped, and comprises a main portion 48, a first fixing portion 46 and a second fixing portion 44 extending from two opposite sides of the main portion 48. The first fixing portion 46 is longer than the main portion 48 and the second fixing portion 44. The second fixing portion 44 has a length similar to that of the main portion 48. The first, second portions 46, 44 and the main portion 48 have top faces (not labeled) coplanar with each other. The main portion 48 has a bottom face lower than that of the first, second fixing portions 46, 44 for contacting with an electronic device (not shown). The first, second fixing portions 46, 44 each define two fixing holes (not labeled) therein for fixing the heat dissipation device to a printed circuit board (not shown) on which the electronic device is mounted. The main portion 48 defines three parallel grooves 49 in the top face thereof for receiving the heat pipes 20 therein. The grooves 49 each have a semicircular cross section.

The first fin set 80 is disposed on the top face of the base 40, and comprises a plurality of first fins (not labeled) assembled together. Each of the first fins is made of a metal sheet with good heat dissipating properties. Each first fin is substantially L-shaped and comprises a first portion 84 located adjacent to the base 40 and a second portion 82 remote from the base 40. The first portions 84 of the fin set 80 thermally contact the top face of the first, second fixing portions 46, 44 and the main portion 48 of the base 40. The fixing holes of the first, second fixing portion 46, 44 are essentially uncovered by the first portions 84 of the first fin set. Each second portion 82 has a lateral side flush with a corresponding lateral side of the first portion 84, and an opposite lateral side extending beyond the second fixing portion 44 of the base 40. First and second flanges 87 perpendicularly extend from corresponding lower edge of the first portion 84 and upper edge of the second portion 82. The first and second flanges 87 of the fins abut against the corresponding first portions 84 and the second portions 82 of the adjacent fins. The first portion 84 defines three grooves 88 in a bottom thereof corresponding to the three grooves 49 of the base 40. The grooves 88 of the first portion 84 each have a semicircular cross section. Three channels 86 are each cooperatively defined by a plurality of through holes (not labeled) defined in the second portion 82 of each first fin, and extend through the first fin set 80 for receiving the heat pipes 20. The three through holes of each second portion 82 of each first fin define a triangle in the second portion 82. The three channels 86 are located at different heights and horizontal portions of the second portions 82 of the first fin set 80.

The two second fin sets 90 are located at two opposite sides of the first fin set 80. Each second fin set 90 comprises a plurality of second fins (not labeled) assembled together. Each of the second fins is made of metal sheet with good heat dissipating properties. Each second fin is substantially L-shaped, and comprises a first dissipating portion 94 at a lower portion thereof and a second dissipating portion 92 at an upper portion thereof. Each second dissipating portion 92 has a lateral side flush with a corresponding lateral side of the first dissipating portion 94, and an opposite lateral side extending beyond a corresponding opposite lateral side of the first dissipating portion 94. First and second flanges 97 perpendicularly extend from corresponding lower edges of the first dissipating portion 94 and upper edge of the second dissipating portion 92. The first and second flanges 97 of the second fins abut against the corresponding first dissipating portions 94 and the second dissipating portions 92 of the adjacent second fins. The first dissipating portion 94 defines three parallel channels 98 extending through the first dissipating portions 94 of the second fin set 90 and corresponding to the grooves 88 of first fin set 80 and the grooves 49 of the base 40, for receiving the heat pipe 20 therein. The channels 98 each have a circular cross section. Corresponding to the channels 86 of the first fin set 80, the second dissipating portions 92 of the second fin set 90 define three through channels 96 therein, for receiving the heat pipe 20 therein. The three channels 96 are located at different heights and horizontal portions of the second dissipating portions 92 of the second fin set 90. The channels 96 each have a circular cross section.

The heat pipes 20 are each substantially U-shaped, and comprise a first transfer section (evaporating section) 22, a second transfer section (condensing section) 24 parallel to the first transfer section 22, and a connecting section 26 connecting with the first and second transfer sections 22, 24. A rounder corner is formed at each joint of the first transfer section 22, the connecting section 26 and the second transfer section 24 of the heat pipe 20.

Middle portions (not labeled) of the first transfer sections 22 of the heat pipes 20 are soldered in the grooves 49 of the main portion 48 of the base 40 and the grooves 88 of the first fin set 80. Side portions of the first transfer sections 22 are interferentially received in the channels 98 of the two second fin sets 90 and located totally within the fins of the second fin sets 90. The second transfer sections 24 of the heat pipes 20 are interferentially received in the channels 86, 96 of the first fin set 80, and the two second fin sets 90. The connecting sections 26 of the heat pipes 20 are located outside one of the two second fin sets 90.

In use, the main portion 48 of the base 40 contacts the electronic device and absorbs heat from the electronic device. The first transfer sections 22 of the heat pipes 20 absorb the heat in the base 40. Part of the heat in the first sections 22 of the heat pipes 20 is transferred to the first portions 84 of the first fin set 80 and the first dissipating portions 94 of the two second fin sets 90, another part of the heat is transferred to the second transfer sections 24 via the connecting sections 26 of the heat pipes 20. Then the heat in the second transfer sections 24 of the heat pipes 20 reaches different portions of the second portions 82 of the first fin set 80 and the second dissipating portions 92 of the two second fin sets 90. The heat in the fins of the first and second fin sets 80, 90 is dissipated to the ambient air.

According to the preferred embodiment of the present invention, the heat dissipation device has the two second fin sets 90 located at two sides of the first fin set 80, and contacts the heat pipes 20 to absorb heat in the heat pipes 20, therefore, the heat absorbed in the heat pipes 20 from the electronic device can be removed to the first and second fin sets 80, 90 rapidly, so that, the heat pipes 20 can be fully utilized to absorb heat from the electronic device. As a result, heat transfer and dissipation capacity of the heat dissipation device are improved. Furthermore, the side portions of the first sections 22 of the heat pipes 20 are located totally within the second fin sets 90, whereby the first sections 22 can have a large contacting area with the second fin sets 90 so that the heat received by the first sections 22 can be quickly transmitted to the second fin sets 90.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device comprising:
a base for absorbing heat from a heat generating device;
a first fin set located on the base;
a second fin set disposed next to the first fin set, the second fin set extending beyond the base; and
a heat pipe for transferring heat from the base to the first fin set and the second fin set, the heat pipe comprising a first section contacting the base, the first fin set and the second fin set, and a second section extending away from the base and contacting the first fin set and the second fin set, wherein the first section has a first portion sandwiched between the base and the first fin set and a second portion extending totally within the second fin set.

2. The heat dissipation device of claim 1 further comprising another second fin set located next to the first fin set and opposite the second fin set, wherein the first section has a third portion extending totally within the another second fin set.

3. The heat dissipation device of claim 1, wherein the first fin set comprises a plurality of fins, each of fins having a first portion located adjacent to the base and a second portion extending remote from the base, the second portion having a lateral side extending beyond a corresponding lateral side of the first portion.

4. The heat dissipation device of claim 3, wherein the second portion of each of the fins of the first fin set laterally extends beyond the base.

5. The heat dissipation device of claim 3, wherein the second portion of each of the fins of the first fin set has an opposite lateral side flush with a corresponding opposite lateral side of the first portion of each of the fins of the first fin set.

6. The heat dissipation device of claim 5, wherein the second portions of the fins of the first fin set define a through channel therein, and the second section of the heat pipe is interferentially received in the channel.

7. The heat dissipation device of claim 1, wherein the second fin set comprises a plurality of fins each comprising a first portion having the first section of the heat pipe extending therethrough, and a second portion having the second section of the heat pipe extending therethrough, the second portions having a lateral side extending beyond a corresponding side of the first portions.

8. The heat dissipation device of claim 7, wherein the second portion of each of the fins of the second fin set has an opposite lateral side flush with a corresponding opposite lateral side of the first portion.

9. The heat dissipation device of claim 7, wherein the second portions of the second fin set define a through channel, the second section of the heat pipe being interferentially received in the channel.

10. The heat dissipation device of claim 1 further comprising two heat pipes each having a first section contacting the base, the first fin set and the second fin set, and a second section extending through the first and second fin sets, the second sections of the three heat pipes are positioned at different heights in the first fin set and the second fin set.

11. The heat dissipation device of claim 10, wherein the second sections of the three heat pipes are positioned at different horizontal positions in the first fin set and the second fin set.

12. A heat dissipation device comprising:
a base for absorbing heat from a heat generating device;
a first fin set disposed on the base;
two second fin sets located on two sides of the first fin set and extending beyond the base;
at least a heat pipe comprising a first section thermally sandwiched between the base and the first fin set and extending totally within the two second fin sets, and a second section extending away from the base and thermally contacting the first fin set and the second fin set.

13. The heat dissipation device of claim 12, wherein the base comprises a main portion and first and second fixing portions extending from two sides of the main portion, the first and second fixing portions defining a plurality of fixing holes therein, the fixing holes being essentially uncovered by the first and second fin sets.

14. The heat dissipation device of claim 13, wherein the first fixing portion of the base is longer than the main portion and the second fixing portion.

15. The heat dissipation device of claim 13, wherein the main portion of the base has a bottom face thereof extending beyond bottom faces of the first and second fixing portions.

16. The heat dissipation device of claim 13, wherein the main portion of the base has a top face coplanar with top faces of the first and second fixing portions.

17. The heat dissipation device of claim 12, wherein the at least a heat pipe comprises a connecting section connecting the first and second section thereof and located next to one of the second fin sets.
